(19) United States
(12) Patent Application Publication
(10) Pub. No.: US 2025/0062749 A1
(43) Pub. Date: Feb. 20, 2025

(54) MULTI-FREQUENCY CAPACITANCE CANCELLATION IN AN ACOUSTIC FILTER CIRCUIT

(71) Applicant: Qorvo US, Inc., Greensboro, NC (US)

(72) Inventor: Nadim Khlat, Cugnaux (FR)

(21) Appl. No.: 18/774,026

(22) Filed: Jul. 16, 2024

Related U.S. Application Data
(60) Provisional application No. 63/520,452, filed on Aug. 18, 2023.
(60) Provisional application No. 63/590,512, filed on Oct. 16, 2023.

(51) Int. Cl. H03H 9/54

(52) U.S. Cl. CPC H03H 9/542

(57) ABSTRACT

Multi-frequency capacitance cancellation in an acoustic filter circuit is provided. The acoustic filter circuit includes an acoustic resonator configured to resonate in a series resonance frequency to pass a radio frequency (RF) signal. However, the acoustic resonator may create an electrical capacitance that can cause the acoustic resonator to resonate at multiple operating frequencies outside the series resonance frequency, thus compromising performance of the acoustic resonator at these operating frequencies. Herein, a negative capacitance circuit is provided in parallel to the acoustic resonator and configured to present multiple negative capacitances to cancel (or at least reduce) the electrical capacitance at the operating frequencies. As a result, it is possible to improve the performance of the acoustic filter circuit across a broader frequency bandwidth.

### RELATED APPLICATIONS

This application claims the benefit of U.S. provisional patent application Ser. No. 63/520,452, filed on Aug. 18, 2023, and U.S. provisional patent application Ser. No. 63/590,512, filed on Oct. 16, 2023, the disclosures of which are hereby incorporated herein by reference in their entireties.

### FIELD OF THE DISCLOSURE

The technology of the disclosure relates generally to cancelling an electrical capacitance at multiple operating frequencies in an acoustic filter circuit.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as Surface Acoustic Wave (SAW) resonators and Bulk Acoustic Wave (BAW) resonators, are used in many high-frequency communication applications. In particular, SAW resonators are often employed in filter networks that operate at frequencies up to 1.8 GHZ, and BAW resonators are often employed in filter networks that operate at frequencies above 1.5 GHz. Such SAW and BAW-based filters have flat passbands, steep filter skirts, and squared shoulders at the upper and lower ends of the passbands, and provide excellent rejection outside of the passbands. SAW and BAW-based filters also have a relatively low insertion loss, tend to decrease in size as the frequency of operation increases, and are relatively stable over wide temperature ranges.

As such, SAW and BAW-based filters are the filter of choice for many 3rd Generation (3G) and 4th Generation (4G) wireless devices and are destined to dominate filter applications for 5th Generation (5G) wireless devices. Most of these wireless devices support cellular, wireless fidelity (Wi-Fi), Bluetooth, and/or near field communications on the same wireless device and, as such, pose extremely challenging filtering demands. While these demands keep raising the complexity of wireless devices, there is a constant need to improve the performance of acoustic resonators and filters that are based thereon.

### SUMMARY

Aspects disclosed in the detailed description include multi-frequency capacitance cancellation in an acoustic filter circuit. The acoustic filter circuit includes an acoustic resonator configured to resonate in a series resonance frequency to pass a radio frequency (RF) signal. However, the acoustic resonator may create an electrical capacitance that can cause the acoustic resonator to resonate at multiple operating frequencies outside the series resonance frequency, thus compromising performance of the acoustic resonator at these operating frequencies. Herein, a negative capacitance circuit is provided in parallel to the acoustic resonator and configured to present multiple negative capacitances to cancel (or at least reduce) the electrical capacitance at the operating frequencies. As a result, it is possible to improve the performance of the acoustic filter circuit across a broader frequency bandwidth.

In one aspect, an acoustic filter circuit is provided. The acoustic filter circuit includes an acoustic resonator. The acoustic resonator is coupled between an input node and an output node. The acoustic resonator is configured to resonate in a series resonance frequency to pass an RF signal from the input node to the output node. The acoustic filter circuit also includes a negative capacitance circuit. The negative capacitance circuit is coupled in parallel to the acoustic resonator between the input node and the output node. The negative capacitance circuit is configured to present multiple negative capacitances each at a respective one of multiple operating frequencies in an operating frequency range nonoverlapping with the series resonance frequency between the input node and the output node.

In another aspect, a wireless device is provided. The wireless device includes an acoustic filter circuit. The acoustic filter circuit includes an acoustic resonator. The acoustic resonator is coupled between an input node and an output node. The acoustic resonator is configured to resonate in a series resonance frequency to pass an RF signal from the input node to the output node. The acoustic filter circuit also includes a negative capacitance circuit. The negative capacitance circuit is coupled in parallel to the acoustic resonator between the input node and the output node. The negative capacitance circuit is configured to present multiple negative capacitances each at a respective one of multiple operating frequencies in an operating frequency range nonoverlapping with the series resonance frequency between the input node and the output node.

In another aspect, a method for cancelling multiple capacitances in an acoustic filter circuit is provided. The method includes configuring an acoustic resonator to resonate in a series resonance frequency to pass an RF signal from an input node to an output node. The method also includes presenting multiple negative capacitances each at a respective one of multiple operating frequencies in an operating frequency range nonoverlapping with the series resonance frequency between the input node and the output node.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary acoustic filter circuit wherein a negative capacitance circuit is configured to present multiple negative capacitances at multiple operating frequencies, respectively;

FIG. 2A is a schematic diagram of the negative capacitance circuit in FIG. 1 configured according to one embodiment of the present disclosure;

FIG. 2B is a schematic diagram of the negative capacitance circuit in FIG. 1 configured according to another embodiment of the present disclosure;

FIG. 3 is a schematic diagram of an exemplary communication device wherein the acoustic filter circuit of FIG. 1 can be provided; and

FIG. 4 is a flowchart of an exemplary process whereby the acoustic filter circuit can be configured to present the negative capacitances at the operating frequencies, respectively.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include multi-frequency capacitance cancellation in an acoustic filter circuit. The acoustic filter circuit includes an acoustic resonator configured to resonate in a series resonance frequency to pass a radio frequency (RF) signal. However, the acoustic resonator may create an electrical capacitance that can cause the acoustic resonator to resonate at multiple operating frequencies outside the series resonance frequency, thus compromising performance of the acoustic resonator at these operating frequencies. Herein, a negative capacitance circuit is provided in parallel to the acoustic resonator and configured to present multiple negative capacitances to cancel (or at least reduce) the electrical capacitance at the operating frequencies. As a result, it is possible to improve performance of the acoustic filter circuit across a broader frequency bandwidth.

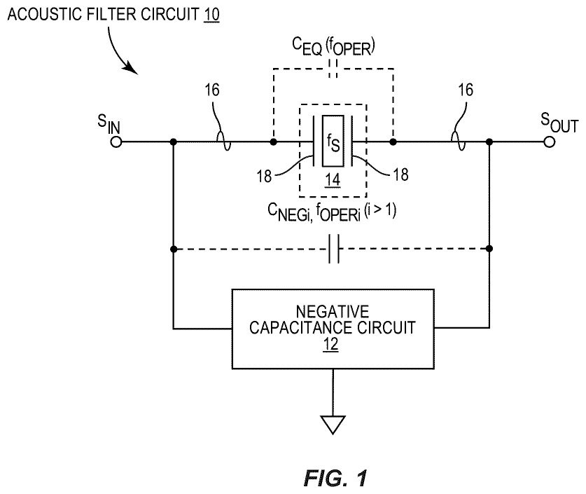

FIG. 1 is a schematic diagram of an exemplary acoustic filter circuit 10 wherein a negative capacitance circuit 12 is configured to present multiple negative capacitances C_{NEGi} (i>1) at multiple operating frequencies f_{OPERi} (i>1) in an operating frequency range f_{OPER} (f_{OPERi}∈f_{OPER}), respectively. The acoustic filter circuit 10 includes an acoustic resonator 14, which is configured to resonate in a series resonance frequency f_{S} to pass a signal 16 from an input node S_{IN} to an output node Sour and block the signal 16 between the input node S_{IN} and the output node Sour in the operating frequency range f_{OPER}. Herein, the series resonance frequency f_{S} and the operating frequency range f_{OPER} are a pair of non-overlapping frequency ranges.

The acoustic resonator 14 is typically made with a pair of metal electrodes 18 that can present an equivalent electrical capacitance C_{EQ} in parallel to the acoustic resonator 14 in each of the operating frequencies f_{OPERi} across the operating frequency range f_{OPER}. The electrical capacitance C_{EQ} may be determined based on equation (Eq. 1) below.

$${C}_{EQ} = {I}_{LOAD} ( t ) / ( \frac{dV ( t )}{dt} ) \qquad ( Eq . 1 )$$

In the equation (Eq. 1) above, I_{LOAD}(t) represents a time-variant load current flowing through a load (not shown) connected to the output node Sour and dV(t)/dt represents a time-variant voltage applied across the acoustic resonator 14. Notably, the electrical capacitance C_{EQ} can cause the acoustic resonator 14 to resonate across the operating frequency range f_{OPER}, thus resulting in parallel resonance in the acoustic resonator 14. Consequently, the acoustic resonator 14 may not be able to effectively block the signal 16 across the operating frequency range f_{OPER}, thus compromising performance of the acoustic resonator 14. As such, it may be desired to eliminate the electrical capacitance C_{EQ} across the operating frequency range f_{OPER}.

In this regard, the negative capacitance circuit 12 is provided in parallel to the acoustic resonator 14 between the input node S_{IN} and the output node S_{OUT}. The negative capacitance circuit 12 can be configured according to various embodiments of the present disclosure to present different negative capacitances C_{NEGi} (i>1) at different operating frequencies f_{OPERi} (i>1) in the operating frequency range f_{OPER} to thereby cancel, or at least reduce, the electrical capacitance C_{EQ} across an entire operating frequency range f_{OPER} of the acoustic resonator 14. By cancelling the electrical capacitance C_{EQ} across the entire operating frequency range f_{OPER} of the acoustic resonator 14, it is possible to improve a signal rejection across the operating frequency range f_{OPER} to thereby improve overall performance of the acoustic filter circuit 10.

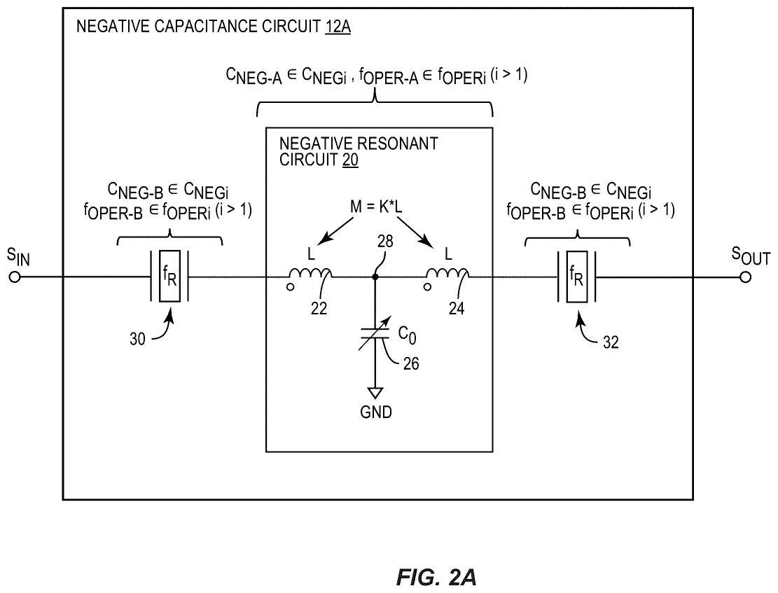

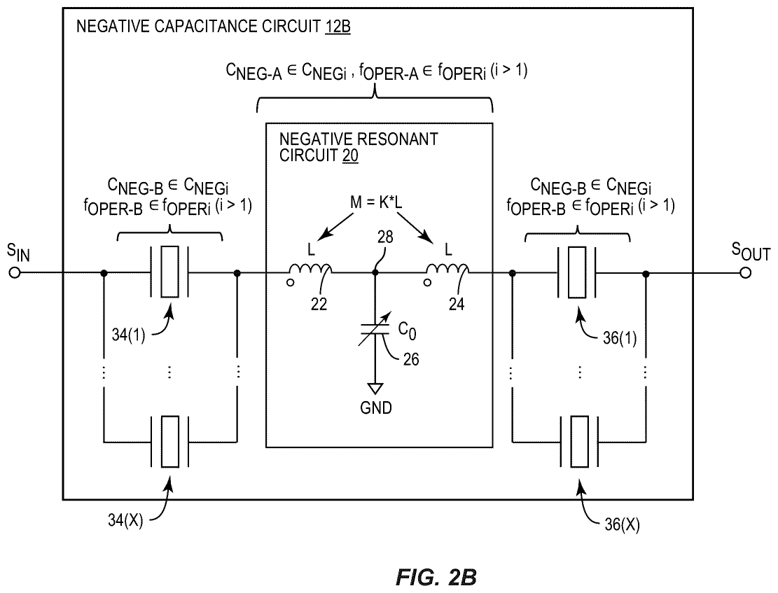

Detailed embodiments of the negative capacitance circuit 12 are now discussed with reference to FIGS. 2A and 2B. Common elements between FIGS. 1, 2A, and 2B are shown therein with common element numbers and will not be re-described herein.

FIG. 2A is a schematic diagram of an exemplary negative capacitance circuit 12A configured according to one embodiment of the present disclosure to be provided in the acoustic filter circuit 10 of FIG. 1 as the negative capacitance circuit 12. The negative capacitance circuit 12A includes a negative resonant circuit 20. The negative resonant circuit 20 includes a pair of negatively coupled inductors 22, 24 and a tunable capacitor 26. The first inductor 22 is coupled between the input node S_{IN} and a middle node 28. The second inductor 24 is coupled between the middle node 28 and the output node S_{OUT}. The tunable capacitor 26 is coupled between the middle node 28 and a ground (GND). The first inductor 22 and the second inductor 24 each has an inductance L and collectively provide a mutual inductance M based on a coupling factor K (0<K<1). The tunable capacitor 26 can be tuned to provide a capacitance C₀, which may be identical to or different from the electrical capacitance C_{EQ}.

The negative capacitance circuit 12A also includes a first acoustic resonator 30 and a second acoustic resonator 32. The first acoustic resonator 30 is coupled between the input node S_{IN} and the negative resonant circuit 20. The second acoustic resonator 32 is coupled between the negative resonant circuit 20 and the output node Sour. Herein, the first acoustic resonator 30 is identical to the second acoustic resonator 32 in that both the first acoustic resonator 30 and the second acoustic resonator 32 will resonate at an identical resonance frequency f_{R}.

In one embodiment, the negative resonant circuit 20 can be configured to present a first negative capacitance C_{NEG-A} (C_{NEG-A}∈C_{NEGi}) at a first operating frequency f_{OPER-A} (f_{OPER-A}∈f_{OPERi}), while both the first acoustic resonator 30 and the second acoustic resonator 32 are both configured to resonate at the first operating frequency f_{OPER-A} to become a short between the signal input S_{IN} and the signal output Sour. In other words, the first operating frequency f_{OPER}-A essentially becomes the series resonance frequency of the first acoustic resonator 30 and the second acoustic resonator 32.

When the first acoustic resonator 30 and the second acoustic resonator 32 are both acting as short circuits, the first negative capacitance C_{NEG-A} and the first operating frequency f_{OPER-A} can be determined as in equations (Eq. 2 and 3) below.

$${C}_{NEG - A} = - \frac{{C}_{0} * K}{2 * ( 1 + K )} \qquad ( Eq . 2 )$$

$${f}_{OPER - A} = \frac{1}{2 π \sqrt{L * {C}_{0} * K}} \qquad ( Eq . 3 )$$

Herein, L represents a respective inductance of the first inductor 22 and the second inductor 24, K represents a coupling factor between the first inductor 22 and the second inductor 24, and C₀ represents a capacitance of the tunable capacitor 26. For a more in-depth description of the negative resonant circuit 20, please refer to U.S. Pat. No. 11,742,818 B2, entitled “WIDE-BANDWIDTH RESONANT CIRCUIT.”

In another embodiment, when the first acoustic resonator 30 and the second acoustic resonator 32 are both configured not to resonate at the first operating frequency f_{OPER}-A, the first acoustic resonator 30 and the second acoustic resonator 32 will no longer act as the short circuit between the input node S_{IN} and the output node S_{OUT}. As a result, the first acoustic resonator 30 and the second acoustic resonator 32 will each present a respective second negative capacitance C_{NEG-B} (C_{NEG-B}∈C_{NEGi}) at a second operating frequency f_{OPER-B} (f_{OPER-B}∈f_{OPERi}). Herein, the second negative capacitance C_{NEG-B} and the second operating frequency f_{OPER-B} can be defined by equations (Eq. 4 and 5) below.

$${C}_{NEG - B} = - \frac{{C}_{0}}{( 1 + N * K )} \qquad ( Eq . 4 )$$

$${f}_{OPER - B} = \frac{1}{2 π \sqrt{L * {C}_{0} * N}} \qquad ( Eq . 5 )$$

In the equations (Eq. 4 and 5), L represents a respective inductance of the first inductor 22 and the second inductor 24, K represents a coupling factor between the first inductor 22 and the second inductor 24, C₀ represents a respective capacitance of the tunable capacitor 26, and N is a positive integer greater than one (N>1). As shown in the equation (Eq. 4), the second negative capacitance C_{NEG-B} can be adjusted by adjusting the capacitance of the tunable capacitor 26 and/or the integer number N. Likewise, as shown in the equation (Eq. 5), the second operating frequency f_{NEG-B} can also be adjusted by adjusting the capacitance of the tunable capacitor 26 and/or the integer number N. As such, the negative capacitance circuit 12A can be tuned to provide any of the negative capacitances C_{NEGi} (i>1) in any of the operating frequencies f_{OPERi} (i>1) in the operating frequency range f_{OPER}.

FIG. 2B is a schematic diagram of an exemplary negative capacitance circuit 12B configured according to one embodiment of the present disclosure to be provided in the acoustic filter circuit 10 of FIG. 1 as the negative capacitance circuit 12. Herein, the negative capacitance circuit 12B includes multiple first acoustic resonators 34(1)-34(X) and multiple second acoustic resonators 36(1)-36(X). The first acoustic resonators 34(1)-34(X) are coupled in parallel between the input node S_{IN} and the negative resonant circuit 20. The second acoustic resonators 36(1)-36(X) are coupled in parallel between the negative resonant circuit 20 and the output node S_{OUT}.

In an embodiment, each of the first acoustic resonators 34(1)-34(X) can be configured according to different integer numbers N. Similarly, the second acoustic resonators 36(1)-36(X) can be configured according to different integer numbers N. Notably, for each of the first acoustic resonators 34(1)-34(X), there shall be a corresponding one of the second acoustic resonators 36(1)-36(X) having an identical integer number N. As such, the first acoustic resonators 34(1)-34(X) and the second acoustic resonators 36(1)-36(X) can collectively provide a set of the second negative capacitance C_{NEG-B} (C_{NEG-B}εC_{NEGi}) at a set of the second operating frequency f_{OPER-B} (f_{OPER-B}∈f_{OPERi}). In this regard, the negative capacitance circuit 12 may concurrently cancel the inherent capacitance C_{EQ} at each of the set of the second operating frequency f_{OPER-B}.

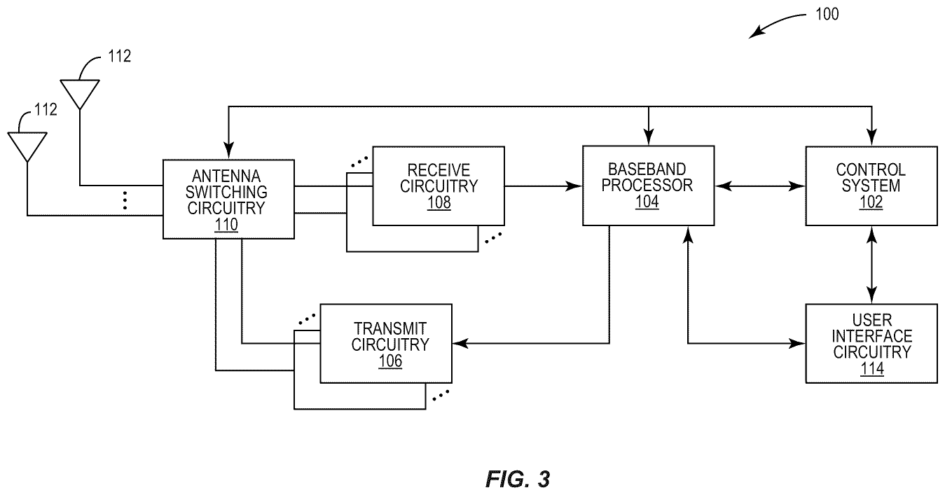

The acoustic filter circuit 10 of FIG. 1 can be provided in a communication device to support the embodiments described above. In this regard, FIG. 3 is a schematic diagram of an exemplary communication device 100 wherein the acoustic filter circuit 10 of FIG. 1 can be provided.

Herein, the communication device 100 can be any type of communication devices, such as mobile terminals, smart watches, tablets, computers, navigation devices, access points, and like wireless communication devices that support wireless communications, such as cellular, wireless local area network (WLAN), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the acoustic filter circuit 10 of FIG. 1 can be provided in the transmit circuitry 106, the receive circuitry 108, and/or the antenna switching circuitry 110. Understandably, the acoustic filter circuit 10 can also be provided anywhere else in the communication device 100.

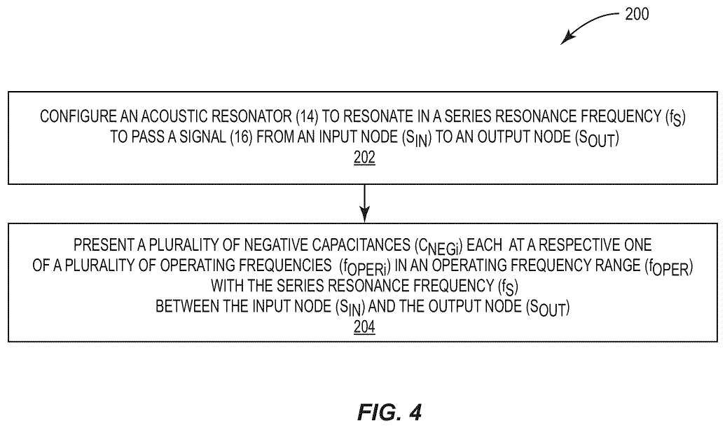

In an embodiment, the acoustic filter circuit 10 can also be tuned in accordance with a process. In this regard, FIG. 4 is a flowchart of an exemplary process 200 for cancelling the inherent capacitance C_{EQ} in the operating frequency range f_{OPER} in the acoustic filter circuit 10 of FIG. 1.

Herein, the process 200 includes configuring the acoustic resonator 14 to resonate in the series resonance frequency f_{S} to pass the signal 16 from the input node S_{IN} to the output node S_{OUT} (step 202). The process 200 also includes presenting the negative capacitances C_{NEGi} each at a respective one of the operating frequencies f_{OPERi} in the operating frequency range f_{OPER} nonoverlapping with the series resonance frequency f_{S} between the input node S_{IN} and the output node S_{OUT} (step 204).

Those skilled in the art will recognize improvements and modifications to the embodiments of the present disclosure. All such improvements and modifications are considered within the scope of the concepts disclosed herein and the claims that follow.

What is claimed is:

1. An acoustic filter circuit comprising:
an acoustic resonator coupled between an input node and an output node and configured to resonate in a series resonance frequency to pass a radio frequency (RF) signal from the input node to the output node; and
a negative capacitance circuit coupled in parallel to the acoustic resonator between the input node and the output node and configured to present a plurality of negative capacitances each at a respective one of a plurality of operating frequencies in an operating frequency range nonoverlapping with the series resonance frequency between the input node and the output node.

2. The acoustic filter circuit of claim 1, wherein the negative capacitance circuit comprises a negative resonant circuit, the negative resonant circuit comprises:
a first inductor coupled between the input node and a middle node;
a second inductor coupled between the middle node and the output node; and
a tunable capacitor coupled between the middle node and a ground.

3. The acoustic filter circuit of claim 2, wherein the negative resonant circuit is configured to present a first negative capacitance among the plurality of negative capacitances at a first operating frequency among the plurality of operating frequencies.

4. The acoustic filter circuit of claim 3, wherein the negative capacitance circuit further comprises:
a first acoustic resonator coupled between the input node and the negative resonant circuit; and
a second acoustic resonator coupled between the negative resonant circuit and the output node.

5. The acoustic filter circuit of claim 4, wherein the first acoustic resonator and the second acoustic resonator are each configured to present a second negative capacitance among the plurality of negative capacitances at a second operating frequency among the plurality of operating frequencies.

6. The acoustic filter circuit of claim 5, wherein the second operating frequency is identical to the first operating frequency.

7. The acoustic filter circuit of claim 5, wherein the second operating frequency is different from the first operating frequency.

8. The acoustic filter circuit of claim 5, wherein:
the second negative capacitance is expressed as: −C₀/(1+N*K); and
the second operating frequency is expressed as: 1/2π\sqrt{L*C₀/N};
wherein:
L represents a respective inductance of the first inductor and the second inductor;
K represents a coupling factor between the first inductor and the second inductor;
C₀ represents a respective capacitance of the tunable capacitor; and
N is a positive integer greater than one.

9. The acoustic filter circuit of claim 2, wherein the negative capacitance circuit further comprises:
a plurality of first acoustic resonators coupled in parallel between the input node and the negative resonant circuit; and
a plurality of second acoustic resonators coupled in parallel between the negative resonant circuit and the output node.

10. The acoustic filter circuit of claim 9, wherein the plurality of first acoustic resonators and the plurality of second acoustic resonators collectively provide a set of second negative capacitances at a set of second operating frequencies, respectively.

11. A wireless device comprising an acoustic filter circuit, the acoustic filter circuit comprising:
an acoustic resonator coupled between an input node and an output node and configured to resonate in a series resonance frequency to pass a radio frequency (RF) signal from the input node to the output node; and
a negative capacitance circuit coupled in parallel to the acoustic resonator between the input node and the output node and configured to present a plurality of negative capacitances each at a respective one of a plurality of operating frequencies in an operating frequency range nonoverlapping with the series resonance frequency between the input node and the output node.

12. The wireless device of claim 11, wherein the negative capacitance circuit comprises a negative resonant circuit, the negative resonant circuit comprises:
a first inductor coupled between the input node and a middle node;
a second inductor coupled between the middle node and the output node; and
a tunable capacitor coupled between the middle node and a ground.

13. The wireless device of claim 12, wherein the negative resonant circuit is configured to present a first negative capacitance among the plurality of negative capacitances at a first operating frequency among the plurality of operating frequencies.

14. The wireless device of claim 13, wherein the negative capacitance circuit further comprises:
a first acoustic resonator coupled between the input node and the negative resonant circuit; and
a second acoustic resonator coupled between the negative resonant circuit and the output node.

15. The wireless device of claim 14, wherein the first acoustic resonator and the second acoustic resonator are each configured to present a second negative capacitance among the plurality of negative capacitances at a second operating frequency among the plurality of operating frequencies.

16. The wireless device of claim 15, wherein the second operating frequency is identical to the first operating frequency.

17. The wireless device of claim 15, wherein the second operating frequency is different from the first operating frequency.

18. The wireless device of claim 12, wherein the negative capacitance circuit further comprises:
a plurality of first acoustic resonators coupled in parallel between the input node and the negative resonant circuit; and
a plurality of second acoustic resonators coupled in parallel between the negative resonant circuit and the output node.

19. The wireless device of claim 18, wherein the plurality of first acoustic resonators and the plurality of second acoustic resonators collectively provide a set of second negative capacitances at a set of second operating frequencies, respectively.

20. A method for cancelling multiple capacitances in an acoustic filter circuit comprising:
configuring an acoustic resonator to resonate in a series resonance frequency to pass a radio frequency (RF) signal from an input node to an output node; and
presenting a plurality of negative capacitances each at a respective one of a plurality of operating frequencies in an operating frequency range nonoverlapping with the series resonance frequency between the input node and the output node.
